(19) United States
(12) Patent Application Publication
(10) Pub. No.: US 2026/0323964 A1
(43) Pub. Date: Oct. 15, 2026

(54) CROSSBAR ARCHITECTURE BASED ON FOUR-PORT NONVOLATILE DEVICE, AND WORK METHOD THEREFOR

(71) Applicant: ZHEJIANG UNIVERSITY, ZHEJIANG (CN)

(72) Inventors: Xunzhao YIN, Zhejiang (CN); Yu Qian, Zhejiang (CN); Cheng ZHUO, Zhejiang (CN)

(73) Assignee: ZHEJIANG UNIVERSITY, ZHEJIANG (CN)

(21) Appl. No.: 19/208,598

(22) Filed: May 15, 2025

(30) Foreign Application Priority Data
Apr. 11, 2025 (CN) 202510451584.2

(51) Int. Cl. H10B 99/00; G11C 11/22; H10B 51/30

(52) U.S. Cl. CPC H10B 99/10; G11C 11/223; G11C 11/2275; H10B 51/30

(57) ABSTRACT

Disclosed is a Crossbar architecture based on a four-port nonvolatile device, and a work method therefor. The Crossbar architecture based on a four-port nonvolatile device includes: a plurality of four-port nonvolatile devices forming an array of n rows×n columns. A front gate of a structure of the four-port nonvolatile device is connected to a word line (WL). A drain of the structure of the four-port nonvolatile device is connected to a data line (DL). A source of the structure of the four-port nonvolatile device is connected to an source line (SL). A back gate is connected to a bulk line (BL). The four-port nonvolatile devices in a same row share one word line (WL). The four-port nonvolatile devices in a same column share one source line (SL) and one data line (DL). All the four-port nonvolatile devices share one bulk line (BL).

### CROSS-REFERENCE TO RELATED APPLICATION

This application claims the priority benefit of China application no. 202510451584.2, filed on Apr. 11, 2025. The entirety of the above-mentioned patent application is hereby incorporated by reference and made a part of this specification.

### BACKGROUND

### Technical Field

The present disclosure relates to the field of storage and vector-matrix-vector-exponential function quaternion multiplication operations, and in particular, to a Crossbar architecture based on a four-port nonvolatile device, and a work method therefor.

### Description of Related Art

The combinatorial optimization problems are widely used in various fields such as logistics, resource allocation, communication network design, finance, drug discovery, and transportation systems. These problems are usually non-deterministic polynomial-time(NP) hard problems and represent some of the most challenging computation tasks in the NP domain.

It is difficult to solve the combinatorial optimization problems by using digital computers based on the Von Neumann architecture, as the required resources increase exponentially in computing power and delay along with expansion of the problem scale. Hence, it is urgent to explore new hardware design and adopt alternative architectures and algorithms to effectively solve the combinatorial optimization problem.

At present, there are numerous solvers based on the Ising model and the quadratic unconstrained binary optimization (QUBO) model for solving these combinatorial optimization problems. The objective functions of these two models involve two operators, that is, vector-matrix-vector multiplication and exponential function computation. However, when implemented, these solvers face high time cost and computational resource cost due to serial computation of the two operators.

In order to solve the above problems and reduce the resource cost of the solvers, the applicant provides a Crossbar architecture based on a four-port nonvolatile device, and a work method therefor.

### SUMMARY

An objective of the present disclosure is to provide a Crossbar architecture based on a four-port nonvolatile device, and a work method therefor for solving the problems of long solving time and high computation cost of solvers based on an Ising model and a quadratic unconstrained binary optimization (QUBO) model at present.

The objective of the present disclosure is achieved through the following technical solution:

A Crossbar architecture based on a four-port nonvolatile device includes: a plurality of four-port nonvolatile devices constituting an array of n rows×n columns, where a front gate of a structure of the four-port nonvolatile device is connected to a word line (WL), and a drain of the structure of the four-port nonvolatile device is connected to a data line (DL); a source of the structure of the four-port nonvolatile device is connected to a source line (SL), and a back gate is connected to a bulk line (BL); and the four-port nonvolatile devices in a same row share one word line (WL), the four-port nonvolatile devices in a same column share one data line (DL) and one source line (SL), and all the four-port nonvolatile devices share one bulk line (BL).

Further, the four-port nonvolatile device is a unit formed by a double-gate ferroelectric field-effect transistor (FeFET).

The present disclosure further provides a work method for the Crossbar architecture. The work method includes:
a preparation stage: before the Crossbar architecture starts to work, storing data for each four-port nonvolatile device in the Crossbar architecture according to a matrix element in a vector-matrix-vector-exponential function to be accelerated; and
a work stage: setting 0 or 1 for each word line (WL) and 0 or 1 for each data line (DL) according to a value of each element in a vector, and applying an analog voltage to a bulk line (BL) according to an input variable of the vector-matrix-vector-exponential function; where in this case, for any four-port nonvolatile device, conduction conditions are as follows: a stored value of the four-port nonvolatile device equals 1, corresponding word line (WL) and data line SL both equal 1, and total currents on all source lines (SLs) are added to indicate a computation result of the vector-matrix-vector-exponential function.

Further, the storing data for each four-port nonvolatile device in the Crossbar architecture according to a matrix element in a vector-matrix-vector-exponential function to be accelerated specifically includes: after information is encoded into a binary sequence, writing the information to each four-port nonvolatile device through the word line (WL), the data line (DL), and the source line(SL).

The present disclosure has the following beneficial effects: the Crossbar architecture based on a four-port nonvolatile device in the present disclosure can accelerate the multiplication operation of the vector-matrix-vector-exponential function and accelerate an operation of an objective function corresponding to a combinatorial optimization problem. The architecture makes full use of a four-port feature, a state of the nonvolatile device is controlled by three signals simultaneously by operating the other three ports except an output port, and then the multiplication operation is performed.

### BRIEF DESCRIPTION OF THE DRAWINGS

FIG. 1 is a schematic diagram of multiplication of a double-gate ferroelectric field-effect transistor (FeFET) using an approximate exponential function of a bulk line (BL).

FIG. 2 is a schematic diagram of a Crossbar architecture based on a four-port nonvolatile device.

### DETAILED DESCRIPTIONS OF THE EMBODIMENTS

The present disclosure will be further described in detail below with reference to accompanying drawings and in conjunction with specific examples.

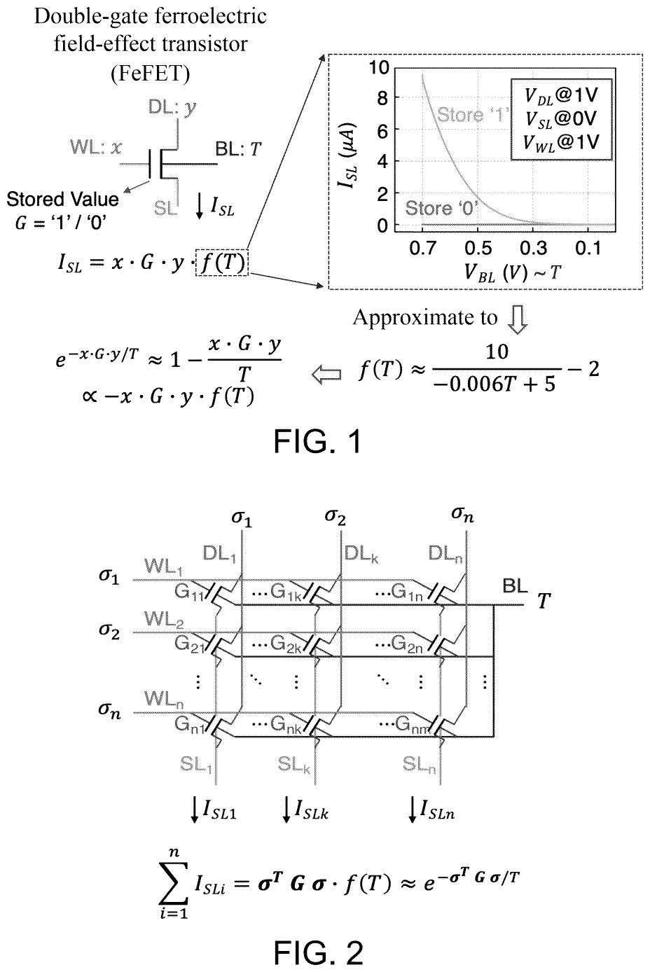

With reference to FIG. 1 and FIG. 2, a Crossbar architecture based on a four-port nonvolatile device includes: a plurality of four-port nonvolatile devices forming an array of n rows×n columns. A front gate of a structure of the four-port nonvolatile device is connected to a word line (WL), and a drain of the structure of the four-port nonvolatile device is connected to a data line (DL). A source of the structure of the four-port nonvolatile device is connected to a source line (SL), and a back gate is connected to a bulk line (BL). The four-port nonvolatile devices in a same row share one word line (WL), the four-port nonvolatile devices in a same column share one data line (DL) and one source line (SL), and all the four-port nonvolatile devices share one bulk line (BL).

As shown in FIG. 1, the four-port nonvolatile device is a unit formed by a double-gate ferroelectric field-effect transistor (FeFET). The double-gate FeFET is a field-effect transistor (FET) structure based on a ferroelectric material, and a structure of the double-gate FeFET is a well-known art, and will not be repeated herein.

The present disclosure further provides a work method for the Crossbar architecture. The work method includes:
a preparation stage: before the Crossbar architecture starts to work, data are stored for each four-port nonvolatile device in the Crossbar architecture according to a matrix element in a vector-matrix-vector-exponential function to be accelerated. The preparation state specifically includes: after information is encoded into a binary sequence, the information is written to each four-port nonvolatile device through the word line (WL), the data line (DL), and the source line(SL).

A work stage: 0 or 1 is set for each word line (WL) and 0 or 1 is set for each data line (DL) according to a value of each element in a vector, and an analog voltage is applied to a bulk line (BL) according to an input variable of an exponential function. In this case, for any four-port nonvolatile device, conduction conditions are as follows: a stored value of the four-port nonvolatile device equals 1, corresponding word line (WL) and data line SL both equal 1, and total currents on all source lines (SLs) are added to indicate a computation result of the vector-matrix-vector-exponential function.

It should be noted that when each double-gate FeFETstores1 and the word line (WL) and the data line (DL) both equal 1, an output current at the source line SL may be adjusted by adjusting a voltage of the bulk line BL, and the output current and the input voltage on the bulk line BL are approximately in the form of a first-order inverse proportional fraction. The form may be used as a first-order Taylor expansion of an exponential function, and the output current may approximate to a computation result of an exponential function of the input voltage on the bulk line (BL).

As shown in FIG. 1, for a single double-gate FeFET device, assuming that a threshold voltage is G, and the WL, the DL and the BL correspond to input variables of x, y and T respectively, the output current at the SL end is the computation result of I_{SL}=x·G·y·f(T). In the formula, f(T) indicates a mapping function between a algorithm parameter T and an actual device output current. Through further analysis, it can be found that a relation between the output current and the input voltage at the BL end is in the form of an inverse proportional function. The form coincides with an approximate result of the first-order Taylor expansion of the function e^{-x·G·y/T}. Thus, under the premise of giving x, y, G and T, G is stored as the threshold voltage, x and y are applied to the WL and the DL in the form of a binary voltage (1 V or 0 V), T is converted into a voltage of f(T) to be applied to the BL, the current at the output end SL is measured and an approximate computation result of the function e^{-x·G·y/T} is obtained.

As shown in FIG. 2, in order to perform computation of the function e^{-σTGσ/T} (in the formula, G denotes a matrix given by the problem itself, σ denotes an input variable in the form of binary vector, and T denotes an algorithm parameter that changes dynamically in the solution process), the matrix G is mapped to the threshold voltage of the double-gate FeFET in the Crossbar at first, and then a corresponding voltage (1 V or 0 V) is applied in a row direction (WL) and a column direction (DL) according to a value of each scalar element in σ. In addition, a function of f(T)~T is derived according to FIG. 1. By applying the voltage with a value of f(T) converted from T to the BL, and measuring and integrating output current values of all columns in the column direction (SL), the computation result of the function e^{-σTGσ/T} may be approximately obtained.

The examples are used to explain the present disclosure rather than limit the present disclosure. Any modification and change made to the present disclosure within the protection scope of the spirit and claims of the present disclosure should fall within the protection scope of the present disclosure.

What is claimed is:

1. A Crossbar architecture based on a four-port nonvolatile device, comprising:
a plurality of four-port nonvolatile devices, forming an array of n rows ×n columns,
wherein a front gate of a structure of the four-port nonvolatile device is connected to a word line,
a drain of the structure of the four-port nonvolatile device is connected to a data line,
a source of the structure of the four-port nonvolatile device is connected to a source line,
a back gate is connected to a bulk line,
the four-port nonvolatile devices in a same row share one word line,
the four-port nonvolatile devices in a same column share one data line and one source line, and
all the four-port nonvolatile devices share one bulk line.

2. The Crossbar architecture based on a four-port nonvolatile device according to claim 1, wherein the four-port nonvolatile device is a unit formed by a double-gate ferroelectric field-effect transistor.

3. A work method for the Crossbar architecture according to claim 1, comprising:
a preparation stage: before the Crossbar architecture starts to work, storing data for each four-port nonvolatile device in the Crossbar architecture according to a matrix element in a vector-matrix-vector-exponential function to be accelerated; and
a work stage: setting 0 or 1 for each word line and 0 or 1 for each data line according to a value of each element in a vector, and applying an analog voltage to the bulk line according to an input variable of the vector-matrix-vector-exponential function,
wherein for any four-port nonvolatile device, conduction conditions are as follows:
a stored value of the four-port nonvolatile device equals 1,
corresponding word line and data line both equal 1, and
total currents on all source lines are added to indicate a computation result of the vector-matrix-vector-exponential function.

4. The work method for the Crossbar architecture according to claim 3, wherein the storing data for each four-port nonvolatile device in the Crossbar architecture according to the matrix element in the vector-matrix-vector-exponential function to be accelerated comprises:
encoding information into a binary sequence, and then writing the information to each four-port nonvolatile device through the word line, the data line, and the source line.
